(19) United States
(12) Patent Application Publication
(10) Pub. No.: US 2020/0002801 A1
(43) Pub. Date: Jan. 2, 2020

(54) VAPOR DEPOSITION MASK AND MANUFACTURING METHOD FOR VAPOR DEPOSITION MASK

(71) Applicant: Sharp Kabushiki Kaisha, Sakai City, Osaka (JP)

(72) Inventor: Shinsaku NAKAJIMA, Sakai City (JP)

(21) Appl. No.: 16/473,279

(22) PCT Filed: Sep. 28, 2017
(86) PCT No.: PCT/JP2017/035188

§ 371 Date: Jun. 25, 2019

(51) Int. Cl. C23C 14/04; C30B 23/04; H01L 51/00

(52) U.S. Cl. CPC C23C 14/042; H01L 51/0011; C30B 23/04

(57) ABSTRACT

A valid portion formed on a mask sheet includes a first region and a second region. The first region is provided for each active region of a vapor deposited substrate, and has a shape corresponding to a shape of each active region. The second region is located outside the first region, and is provided with a covering portion configured to cover a plurality of vapor deposition holes.

### TECHNICAL FIELD

The disclosure relates to a vapor deposition mask and a manufacturing method for the vapor deposition mask.

### BACKGROUND ART

As described in PTL 1, a vapor deposition mask is used in the case of patterning and forming a light-emitting layer on each pixel in an organic EL display device.

As illustrated in FIG. 15A, a plurality of covering sheets 112 each having a sheet shape and a plurality of hauling sheets 113 each having a sheet shape are attached to a mask frame 111 having a frame shape and including an opening of the frame 111a, to intersect each other at a right angle in a lattice pattern.

At the time of attachment of the plurality of covering sheets 112 and the plurality of hauling sheets 113 to the mask frame 111, both end portions and portions near both the end portions of the plurality of covering sheets 112 and the plurality of hauling sheets 113 are welded to the mask frame 111 while both the end portions of the plurality of covering sheets 112 and the plurality of hauling sheets 113 are stretched (pulled) outward.

Accordingly, the plurality of covering sheets 112 are attached to the mask frame 111 so as to be parallel to each other in a short-hand direction (left-right direction on the paper surface) perpendicular to a longitudinal direction (up-down direction on the paper surface) of the mask frame 111. In addition, the plurality of hauling sheets 113 are attached to the mask frame 111 to be parallel to each other in the longitudinal direction of the mask frame 111.

Next, an alignment sheet 114 having an alignment mark formed is attached to the mask frame 111 along a shorter side of the opening of the frame 111a to make the alignment mark located at a predetermined position.

Then, both end portions of the plurality of mask sheets 115 each having a strip shape and portions near both the end portions of the mask sheets 115 are welded to the mask frame 111 by using the alignment mark as a reference while both the end portions of the mask sheets 115 are stretched (pulled) outward.

The mask sheets 115 each include a plurality of valid portions 115a formed. The valid portions 115a are regions in which a plurality of vapor deposition holes for vapor-depositing a vapor-deposition layer for each pixel on the vapor deposited substrate are formed to be arranged.

In an example in FIGS. 15A and 15B, the valid portions 115a each have a shape corresponding to a shape of an active region of the vapor deposited substrate.

As illustrated in FIG. 15B, the plurality of mask sheets 115 are stretched and welded to cause the valid portions 115a to be present in all openings defined by the plurality of covering sheets 112 and the plurality of hauling sheets 113. Then, unnecessary portions located outside of the welded portions of the plurality of mask sheets 115 are cut off. Accordingly, a vapor deposition mask 110 is complete.

At the time of performing vapor deposition by using the vapor deposition mask 110, vapor deposition particles vaporized or sublimated from the vapor deposition source pass through the vapor deposition holes of the valid portions 115a, and are attached on the pixels of the vapor deposited substrate. The vapor deposition particles attached on the pixels serve as a light-emitting layer. Hence, the valid portions 115a each have a shape corresponding to the shape of the active region of the vapor deposited substrate, and a pattern is formed in a region having area smaller than area of each of the openings defined by the plurality of covering sheets 112 and the plurality of hauling sheets 113. Then, a position of the light-emitting layer vapor-deposited on the vapor deposited substrate is determined by a position of an opening pattern provided in each vapor deposition hole of the vapor deposition mask, and the external shape of the active region of the vapor deposited substrate on which the light-emitting layer is vapor-deposited is determined by an external shape of each of the valid portions 115a.

In particular, since the plurality of vapor deposition holes corresponding to the pixels are formed in each of the mask sheets 115 including the valid portions 115a formed as described above, the mask sheets 115 needs to be attached to the mask frame 111 with high positional accuracy.

According to the mask sheets 115, since the valid portions 115a each have a rectangular shape, even when outward force is applied to both the end portions of the mask sheets 115 at the time of attachment of the mask sheets 115 to the mask frame 111, stress applied on the periphery of the valid portion 115a is easily made uniform, and the mask sheets 115 can be attached to the mask frame 111 with relatively high positional accuracy.

### CITATION LIST

### Patent Literature

PTL 1: JP 2012-132096 A

### SUMMARY

### Technical Problem

In the related art, an external shape of a display region of an organic EL display device has a square or rectangular shape commonly applied to a smartphone or the like, and has been easy to prepare.

In recent years, a flexible (bendable) organic EL display device has been developed by using a film, rather than glass, as a support body. In particular, in such a flexible organic EL display device, the support body is formed of a film, rather than glass, and hence, the flexible organic EL display device can be easy to machine into various shapes.

Then, for example, to differentiate a smartphone or other electronic devices in terms of design, there has been a demand for the external shape of the display region different from a square or rectangular shape such as a shape in which each corner is provided with a rounded shape (round shape), and a shape in which a notch (recess) for disposing a camera or speaker is provided.

In a case where a light-emitting layer is present in such a cut portion having an irregular shape, a portion of the light-emitting layer is not sealed and exposed at a sealing step subsequently performed land hence, reliability cannot be secured. Hence, at a vapor deposition step for vapor-depositing the light-emitting layer, it is necessary to perform masking not to vapor-deposit the light-emitting layer in the cut portion having an irregular shape.

In addition, in a case where an external shape of a valid portion 115a of a mask sheet 115 illustrated in FIG. 15 is set to, for example, correspond to a shape of the cut portion having an irregular shape of the active region and to be the same shape as the shape of the cut portion having an irregular shape as illustrated in FIGS. 16 and 17 to be described later, positional accuracy of the vapor deposition hole deteriorates at the time of attachment of the mask sheet 115 to the mask frame 111. Further, in recent years, there is an increasing demand for pixels having higher resolution, and hence, there is an increasing demand for attachment of the mask sheet 115 to the mask frame 111 while a decrease in positional accuracy for vapor deposition holes is prevented.

The disclosure has been made in view of the above-described problems of the related art, and an object of the disclosure is to provide a vapor deposition mask that can be used for patterning and forming a vapor-deposition layer with high accuracy even when an active region has an irregular shape different from a square or rectangular shape.

### Solution to Problem

In order to solve the problems described above, a vapor deposition mask according to one aspect of the disclosure provides a vapor deposition mask configured to be used to vapor-deposit a vapor-deposition layer on each of pixels of a vapor deposited substrate provided with a plurality of active regions on which the pixels contributing to displaying are arranged, the vapor deposition mask including: a mask sheet provided with a valid portion provided for each of the plurality of active regions and including a plurality of vapor deposition holes, wherein the valid portion includes a first region and a second region, the first region has a shape corresponding to a shape of each of the plurality of active regions, and the second region is a region different from the first region, and is provided with a covering portion configured to cover a portion of the plurality of vapor deposition holes.

In order to solve the problems described above, a manufacturing method for a vapor deposition mask according to one aspect of the disclosure provides a manufacturing method for a vapor deposition mask used to vapor-deposit a vapor-deposition layer on each of pixels of a vapor deposited substrate provided with a plurality of active regions on which the pixels contributing to displaying are arranged, the method including: a vapor-deposition-hole forming step for forming a plurality of vapor deposition holes in a mask sheet to provide a valid portion for each of the plurality of the active regions; and a covering-portion forming step for forming, outside of a shape of the valid portion corresponding to a shape of each of the plurality of active regions in the valid portion, a covering portion configured to cover a portion of the plurality of vapor deposition holes, to provide a first region having a shape corresponding to a shape of each of the plurality of active regions and to provide a second region provided with the covering portion.

Advantageous Effects of Disclosure

According to an aspect of the disclosure, an effect in which patterning and forming of a vapor-deposition layer can be performed with high accuracy even when an active region has an irregular shape different from a square or rectangular shape.

### BRIEF DESCRIPTION OF DRAWINGS

FIGS. 1A and 1B are views each illustrating a configuration of an organic EL display device according to a first embodiment.

FIG. 2 is a view illustrating manufacturing steps for an organic EL display panel according to the first embodiment.

FIG. 3 is a plan view illustrating a substrate of the organic EL display device according to the first embodiment.

FIG. 4 is a cross-sectional view illustrating an organic EL display panel formation region of a substrate illustrated in FIG. 3.

FIG. 5 is a schematic view illustrating a state at a vapor deposition step for forming a light-emitting layer of the organic EL display device according to the first embodiment.

FIG. 6 is an enlarged view of a portion of an active region 3 according to the first embodiment.

FIG. 7 is a view illustrating the vapor deposition step for the light-emitting layer of the organic EL display panel according to the first embodiment.

FIGS. 8A to 8F are views each illustrating a state where a vapor deposition mask according to the first embodiment is prepared.

FIGS. 9A to 9D are views each illustrating a configuration of a mask sheet according to the first embodiment.

FIGS. 10A and 10B are views each illustrating a state where a covering portion is formed on a valid portion in the mask sheet according to the first embodiment.

FIG. 11 is a view illustrating a state of a portion of the vapor deposition mask according to the first embodiment as viewed from a second surface side.

FIG. 12 is a cross-sectional view illustrating a vapor deposition mask and a TFT substrate at the time of performing vapor deposition at a vapor deposition step according to the first embodiment.

FIG. 13 is a view illustrating a vapor deposition step for a light-emitting layer of an organic EL display panel according to a second embodiment.

FIGS. 14A to 14F are views each illustrating a state where a vapor deposition mask according to the second embodiment is prepared.

FIGS. 15A and 15B are views each illustrating a state where a vapor deposition mask of the related art is prepared: FIG. 15A is a view illustrating a state where a mask sheet is attached to a mask frame, and FIG. 15B is a plan view illustrating the vapor deposition mask prepared.

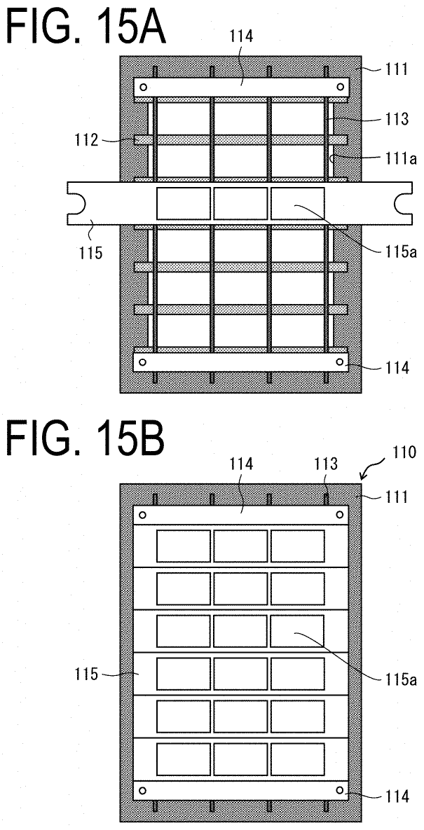

FIG. 16 is a plan view illustrating a configuration of a mask sheet according to a comparative example in which an external shape of a valid portion is an irregular shape.

FIG. 17 is a plan view illustrating a configuration of a modification example of the mask sheet according to the comparative example in which the external shape of the valid portion has an irregular shape.

FIG. 18 is a view illustrating a configuration of the mask sheet according to the first embodiment provided with a floating island portion.

### DESCRIPTION OF EMBODIMENTS

### First Embodiment

Configuration of Electronic Device 30

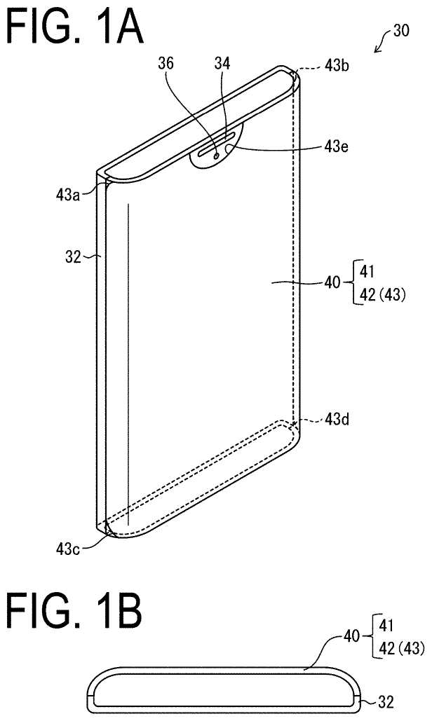

FIG. 1A is a perspective view illustrating external appearance of an electronic device 30 in which an organic EL display device according to a first embodiment of the disclosure is used, and FIG. 1B is a cross-sectional view of FIG. 1A. An example of the electronic device 30 includes a smartphone. However, the electronic device 30 is not limited to a smartphone, and may be any electronic device including an organic EL display panel (display panel having an irregular shape) 42 incorporated, such as a mobile information terminal such as other mobile phone terminals or a tablet, a television receiver, and a personal computer.

The electronic device 30 includes a housing 32. Then, the electronic device 30 includes a touch panel 40, a speaker 34, a camera 36, and a not-illustrated microphone, each of which is provided in the housing 32. In addition, the electronic device 30 may include various types of buttons such as a power button for switching between power-on and power-off.

The touch panel 40 includes a touch sensor 41 and an organic EL display panel 42. The organic EL display panel 42 includes a display region 43 having an irregular shape and configured to display various images. The organic EL display panel 42 includes the display region 43 and a frame region surrounding the periphery of the display region 43. Various parts are attached to the organic EL display panel 42 to constitute an organic EL display device (display device).

The touch sensor 41 is provided in the organic EL display panel 42. The touch sensor 41 is an input device configured to detect an input operation by contact or approaching of a finger, a stylus pen, or the like to receive, from a user, an input of a coordinate position on the organic EL display panel 42. The touch sensor 41 may be formed integrally with the organic EL display panel 42, or may be formed as a separate configuration from the organic EL display panel 42. The touch sensor 41 may be of a type capable of receiving an input operation from a user such as a capacitive type or an infrared type.

The external shape of the display region 43 of the organic EL display panel 42 is not a rectangular or square shape, but is an irregular shape different from the rectangular or square shape.

The irregular shape refers to a shape in which in a case where an external shape of an organic EL display panel is a rectangular or square shape, at least a portion of an edge (a side or a corner) of the external shape of the organic EL display panel having the rectangular or square shape includes an irregular-shape portion protruding inwardly (in a central portion direction of the rectangular or square shape) or outwardly (in a direction away from the central portion of the rectangular or square shape) from the edge. That is, the irregular-shape portion refers to a portion having a shape different from the rectangular or square shape in a case where the external shape of the organic EL display panel is the rectangular or square shape.

In FIGS. 1A and 1B, in the display region 43 of the organic EL display panel 42, four corners 43a to 43d each have, for example, a shape curved rather than right-angled (arc shape), that is, a so-called rounded shape (round shape). Further, the display region 43 of the organic EL display panel 42 has, for example, a shape in which at least one side of four sides includes a notched portion 43d recessed to protrude from an edge in a central portion direction of the display region 43. The notched portion 43d has, for example, an arc shape. An external shape of the frame region of the organic EL display panel 42 has a small width, and is substantially the same shape as the external shape of the display region 43.

In addition, as illustrated in FIG. 1B, in this embodiment, the display region 43 of the organic EL display panel 42 has a cross section in which both longer sides and the vicinity of both the longer sides are curved.

The camera 36 and the speaker 34 are disposed in a region of the housing 32 surrounded by the notched portion 43d.

Note that the shape of the external shape of this organic EL display panel 42 is merely an example, and may be another irregular shape. Hereinafter, a manufacturing method for this organic EL display panel 42 having the external shape of an irregular shape will be described.

Outline of Manufacturing Method for Organic EL Display Panel

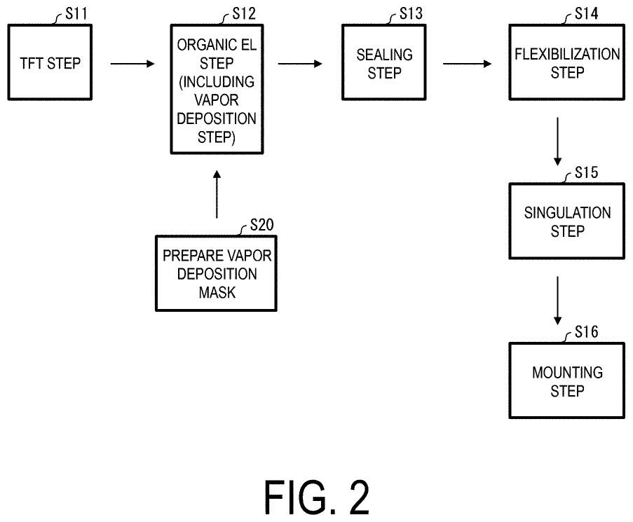

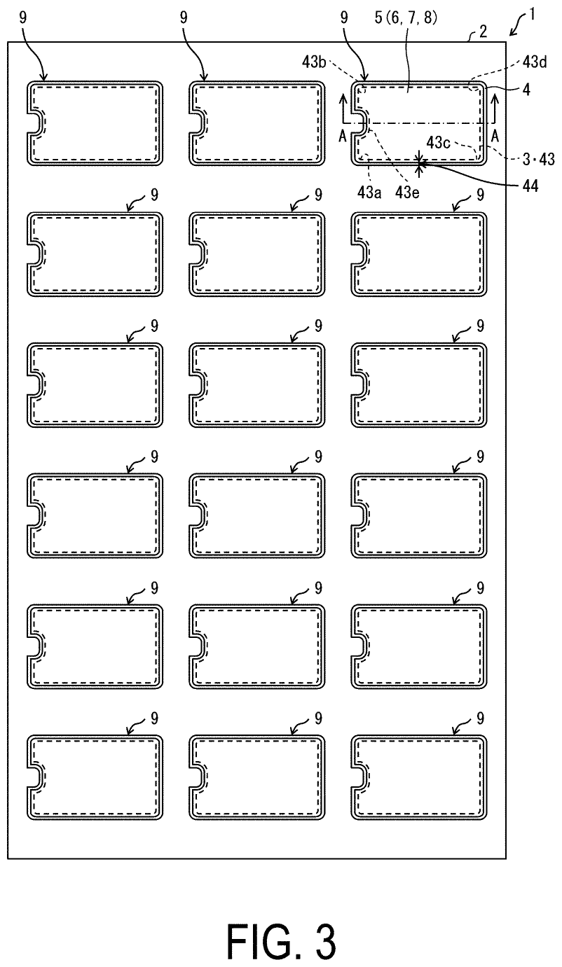

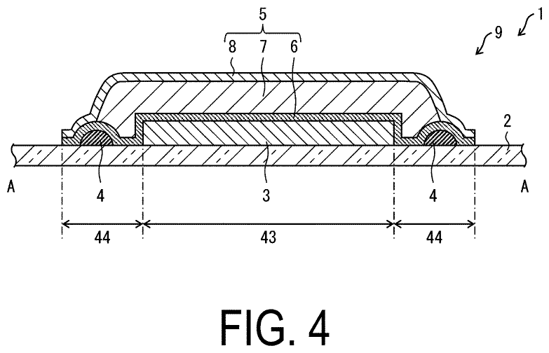

FIG. 2 is a view illustrating manufacturing steps for the organic EL display panel according to the first embodiment. FIG. 3 is a plan view illustrating a substrate 1 of the organic EL display panel according to the first embodiment of the disclosure. FIG. 4 is a cross-sectional view illustrating an organic EL display panel formation region of the substrate illustrated in FIG. 3. FIG. 3 illustrates a configuration in a case where 18 pieces of organic EL display panels are obtained from one mother glass. Note that the number of the organic EL display panels obtained from one mother glass is not limited to 18, and may be 17 or less or may be 19 or more.

On the substrate 1, 18 pieces of organic EL display panel formation regions 9 are disposed. Each of the organic EL display panel formation regions 9 is a region cut out from the mother glass into an individual piece and then being to be an organic EL display panel.

The substrate 1 includes a TFT substrate (vapor deposited substrate) 2, an active region 3, a frame-shaped bank 4, and a sealing layer 5.

A plurality of the active regions 3 are provided in a matrix shape. The active regions 3 are, for example, regions in which pixels of RGB are formed, respectively. In the organic EL display panel formation region 9, a region where the active region 3 is formed serves as the display region 43, and a peripheral region surrounding the active region 3 serves as a formation region 44. Note that, in FIG. 3, the frame region 44 is a region located outside of a region (active region 3) indicated by a dashed line in the organic EL display panel formation region 9.

As illustrated in FIGS. 2 to 4, the TFT substrate 2 is first prepared at TFT step S11. The TFT substrate 2 is prepared by forming, on a mother glass, a film serving as a base for a flexible substrate by using a material such as polyimide, forming, on the film by a known method, various types of wiring lines present in a pixel circuit provided for each pixel such as a TFT (a transistor and a driving element), a gate wiring line, and a source wiring line, forming a passivation film (protection film), an interlayer insulating film (surface leveling film), and the like, and further forming, on the inorganic insulating film, a reflective electrode layer being in contact with an anode, an ITO layer, and a pixel bank (edge cover) for defining a light emitting region.

Accordingly, the light emitting region is formed on the active region 3.

The passivation film prevents peeling of the metal film in the TFT, and protects the TFT. The passivation film is formed on the mother glass or via another layer, and covers the TFT. The passivation film is an inorganic insulating film including silicon nitride, silicon oxide, and the like.

The interlayer insulating film provides a leveled surface over irregularities on the passivation film. The interlayer insulating film is formed on the passivation film. The interlayer insulating film is an organic insulating film made of a photosensitive resin such as acrylic, or made of a thermoplastic resin such as polyimide.

In addition, at the time of forming this active region 3, the frame-shaped bank 4 surrounding the active region 3 in a frame shape is also formed on the TFT substrate 2. The frame-shaped bank 4 is made of a photosensitive resin such as acrylic, or of a thermoplastic resin such as polyimide.

Next, at organic EL step S12, an organic EL layer is formed on the reflective electrode layer in each pixel (that is, in an opening of the pixel bank formed at TFT step S11) of the TFT substrate 2. The organic EL layer includes the light-emitting layer, a hole transport layer, and other function layers. The light-emitting layer emits, for each pixel, light of a different color such as red, green, or blue. At a vapor deposition step, a layer (vapor-deposition layer) vapor-deposited for each pixel such as the light-emitting layer and the hole transport layer is formed at a predetermined position of each pixel by vapor deposition performed in a vacuum by using the vapor deposition mask according to this embodiment.

Prior to the vapor deposition step, the vapor deposition mask to be used at the vapor deposition step for forming the vapor-deposition layer vapor-deposited for each pixel such as the light-emitting layer and the hole transport layer is prepared in advance at prepare step S20 for the vapor deposition mask. Note that details of prepare step S20 for the vapor deposition mask will be described later. In addition, the layer formed by using this vapor deposition mask is not limited to the light-emitting layer and the hole transport layer, and may be a layer formed for each pixel (that is, in the opening of the pixel bank).

Then, a transparent electrode facing the reflective electrode via the organic EL layer is formed to cover the organic EL layer.

Then, next, the sealing layer 5 is formed at sealing step S13. As an example, the sealing layer 5 can include a three layer structure in which the inorganic layer 6, the organic layer 7, and the inorganic layer 8 are layered in this order from the TFT substrate 2 side. Since the frame-shaped bank 4 is formed, the organic film 7 can have a large film thickness of, for example, 1.0 μm or greater.

After this sealing layer 5 is formed, flexible step S14 is performed. At flexible step S14, glass of the substrate is peeled off, and a film or the like serving as a support body is affixed.

Then, next, at singulation step S15, each of the organic EL display panel formation regions 9 is cut out. Accordingly, each of the organic EL display panel formation regions 9 is formed into an individual piece. Accordingly, a display panel (organic EL display panel) having flexibility and an irregular shape is formed.

Next, at mounting step S16, a member such as a driver is mounted on each of the organic EL display panel formation regions 9 formed into an individual piece. Accordingly, the organic EL display device is complete.

In this embodiment, the active region 3 has, for example, an irregular shape different from a rectangular or square shape, and hence, the external shape of the display panel also has an irregular shape corresponding to the shape of the active region 3.

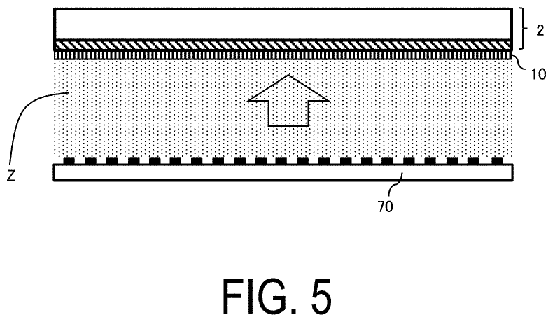

FIG. 5 is a schematic view illustrating a state at the vapor deposition step performed at the time of forming the vapor-deposition layer of the organic EL display device according to the first embodiment of the disclosure.

At the vapor deposition step for vapor-deposit the vapor-deposition layer, a vapor deposition mask 10 provided with a mask sheet 15 having a plurality of through-holes is brought into close contact with the TFT substrate 2, and in a vacuum, vapor deposition particles Z (for example, an organic light-emitting material) caused to evaporate with a vapor deposition source 70 are vapor-deposited on the pixels of the TFT substrate 2 through the mask sheet 15. Accordingly, a vapor deposition pattern being a pattern corresponding to each through-hole of the mask sheet 15 is formed on the TFT substrate 2.

Here, the external shape of the active region 3 (see, FIGS. 1A and 1B, 3, and 4) has an irregular shape different from a rectangular or square shape. For example, the active region 3 has an irregular shape in which each of the four corners 43a to 43d is formed into a round shape, rather than a right-angle shape, and further at least one side of the four sides includes the notched portion 43d recessed from the edge in the central portion direction of the display region 43. Hence, the vapor deposition mask used at the vapor deposition step also has vapor deposition holes formed to be arranged to correspond to the shape of the active region 3.

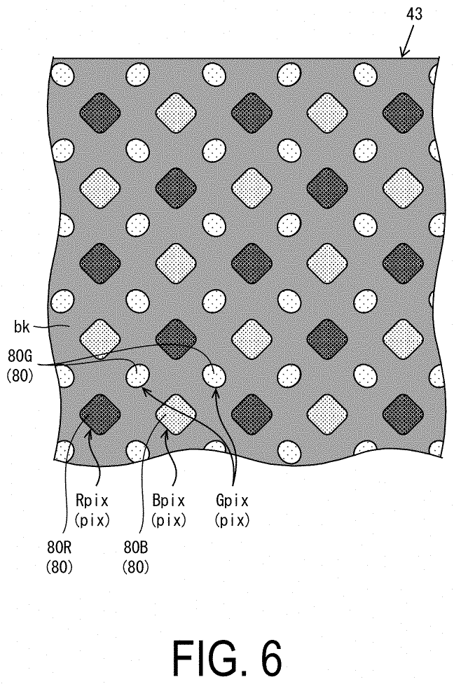

FIG. 6 is an enlarged view of a portion of the active region 3 according to the first embodiment. On the active region 3, pixels pix contributing to displaying of an image are disposed to be arranged in a matrix shape. On each of the pixels pix, the light-emitting layer 80 is formed. A peripheral region surrounding the pixels pix serves as a pixel bank bk.

As an example, in FIG. 6, a red pixel Rpix on which a red light-emitting layer 80R configured to emit red light is formed, a green pixel Gpix having a red light-emitting layer 80G configured to emit green light, and a blue pixel Bpix having a blue light-emitting layer 80B configured to emit blue light are arranged in a pentile matrix. However, the pixel arrangement is not particularly limited to the pentile matrix, and may be other arrangement such as stripe arrangement.

Note that a shape of the light-emitting layer 80 is a shape of the opening of the pixel bank bk in which the light-emitting layer 80 is formed.

### Vapor Deposition Mask

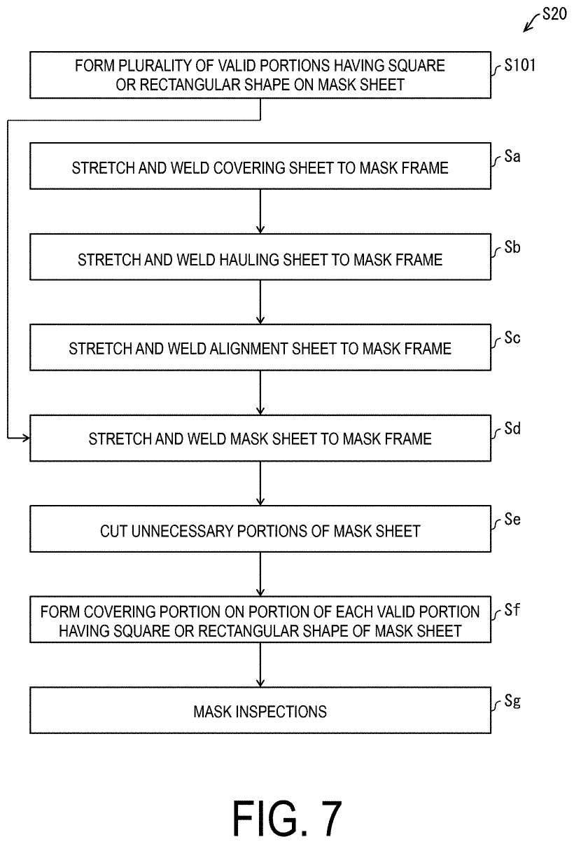

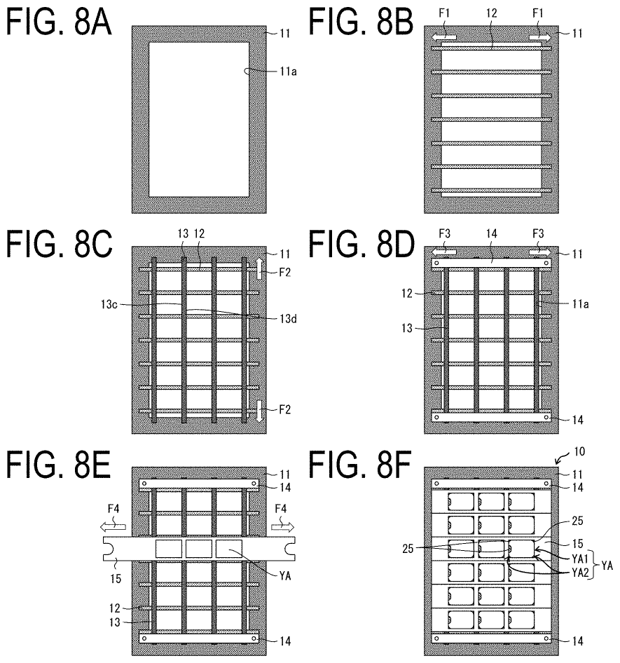

Next, prepare step S20 for the vapor deposition mask used at the vapor deposition step will be described. FIG. 7 is a view illustrating the vapor deposition step for the light-emitting layer of the organic EL display panel according to the first embodiment. FIGS. 8A to 8F are views each illustrating a state where the vapor deposition mask according to the first embodiment is prepared. FIG. 8A is a plan view illustrating the mask frame. FIG. 8B is a view illustrating a state where a covering sheet is attached to the mask frame. FIG. 8C is a view illustrating a state where a hauling sheet is attached to the mask frame. FIG. 8D is a view illustrating a state where an alignment sheet is attached to the mask frame. FIG. 8E is a view illustrating a state where a mask sheet is attached to the mask frame. FIG. 8F is a plan view illustrating the vapor deposition mask prepared.

As illustrated at step Sa in FIG. 7 and illustrated in FIGS. 8A and 8B, a plurality of covering sheets 12 are attached to the mask frame 11 having a frame shape and including an opening of the frame 11a in a region surrounded by the frame (covering-sheet attachment step).

For example, an invar material or the like having a significantly low thermal expansion and a thickness ranging from 20 mm to 30 mm is used as a base material of the mask frame 11. The mask frame 11 is sufficiently thick as compared to the mask sheet, and has increased rigidity to enable sufficient accuracy to be secured even at the time of stretching and welding of the mask sheet.

The covering sheets 12 each serve to fill a gap between the mask sheets to be subsequently attached to the mask frame 11, and close a dummy pattern formed on the mask sheet.

For example, an invar material or the like having a thickness ranging from 30 μm to 50 μm is used as a base material of the covering sheets 12. The covering sheets 12 each have an elongated shape, and extends in a straight manner from one end portion to the other end portion.

At the time of attachment of the covering sheets 12 to the mask frame 11, both end portions of the covering sheets 12 are welded to the inside of a groove provided in the mask frame 11 while each of both the end portions of the covering sheets 12 is stretched (pulled) by application of force to each of both the end portions of the covering sheets 12 in an outward direction (in a direction away from each other) as indicated by arrow F1 in FIG. 8B. Then, unnecessary portions located outside of the welded portions of the covering sheets 12 are cut off. Accordingly, each of the covering sheets 12 is attached at a predetermined position of the mask frame 11. In this embodiment, the covering sheets 12 are attached to the mask frame 11 to be parallel to each other in a shorter side direction of the mask frame 11. The covering sheets 12 are attached to the mask frame 11 to be arranged on a longer side of the mask frame 11 and to be parallel to each other.

Next, as illustrated at step Sb in FIG. 7 and illustrated in FIG. 8C, hauling sheets 13 (also referred to as support sheets) are attached to the mask frame 11 to which the covering sheets 12 are attached (hauling-sheet attachment step).

The hauling sheets 13 each serve to support the mask sheet to be subsequently attached to the mask frame 11 and not to loosen, and serve to close a dummy pattern formed on the mask sheet.

For example, an invar material or the like having a thickness ranging from 30 μm to 100 μm is used as a base material of the hauling sheets 13. A width of each of the hauling sheets 13 ranges, for example, from approximately 8 mm to 10 mm, and is determined according to layout on a substrate on which a panel is disposed. The howling sheet 13 has an elongated shape, and extends in a straight manner from one end portion to the other end portion.

In a display panel having a portrait shape, a terminal portion is typically masked with a hauling sheet, and hence, the width of the hauling sheet is larger than a width of the covering sheet. However, the hauling sheet is disposed at a position not overlapping with the display region (namely, the valid portion of the mask sheet) of the display panel.

At the time of attachment of the hauling sheets 13 to the mask frame 11, both end portions of the hauling sheets 13 are welded to the inside of the groove provided in the mask frame 11 while both the end portions of the hauling sheets 13 are stretched (pulled) by application of force to each of both the end portions of the hauling sheets 13 in an outward direction (in a direction away from each other) as indicated by arrow F2 in FIG. 8C. Then, unnecessary portions located outside of the welded portions of the hauling sheets 13 are cut off. Accordingly, each of the hauling sheets 13 is attached at a predetermined position of the mask frame 11.

In this embodiment, each of the hauling sheets 13 is attached to the mask frame 11 to be parallel to the longer side of the mask frame 11. The hauling sheets 13 are attached to the mask frame 11 to be arranged in the shorter side direction of the mask frame 11 and to be parallel to each other.

Note that the order of attachment of the covering sheets 12 and the hauling sheets 13 to the mask frame 11 may be reversed (reverse the order of step S a and step Sb in FIG. 7), and the hauling sheets 13 are first attached to the mask frame 11, and then, the covering sheets 12 are attached to the mask frame 11.

The plurality of covering sheets 12 and the plurality of hauling sheets 13 are attached to the mask frame 11 in a lattice pattern as illustrated in FIG. 8C, and accordingly, openings each defined by the covering sheets 12 facing each other and the hauling sheets 13 facing each other are formed to be arranged.

Next, as illustrated at step Sc in FIG. 7 and illustrated in FIG. 8D, an alignment sheet 14 including an alignment mark formed is attached to the mask frame 11 to make the alignment mark located at a predetermined position (alignment-sheet attachment step).

At the time of attachment of the alignment sheet 14 to the mask frame 11, both end portions of the alignment sheet 14 are welded at predetermined positions of the mask frame 11 while both the end portions of the alignment sheet 14 are stretched (pulled) by application of force to each of both the end portions of the alignment sheet 14 in an outward direction (in a direction away from each other) and in a direction parallel to the short-hand direction of the mask frame 11 as indicated by arrow F3 in FIG. 8D. Then, unnecessary portions located outside of the welded portions of the alignment sheet 14 are cut off. Accordingly, the alignment sheet 14 is attached at a predetermined position of the mask frame 11. In this embodiment, two alignment sheets 14 are attached to the mask frame 11 to be parallel to each other along a shorter side of the opening of the mask 11a of the mask frame 11.

Next, as illustrated at step Sd in FIG. 7 and illustrated in FIG. 8E, a plurality of the mask sheets 15 are attached to the mask frame 11 (mask-sheet attachment step). The mask sheets 15 are sheets used, for example, for separately patterning RGB to pattern and form the vapor-deposition layer in the pixels in the active region 3 illustrated in FIGS. 3 and 4.

Prior to this step Sd and before the mask sheets 15 are attached to the mask frame 11, the vapor deposition holes each having a square or rectangular shape are formed to be arranged, and a plurality of valid portions YA are formed on each mask sheet 15 at step S101 (valid-portion forming step). The valid portion YA is formed for each active region 3. Details of a structure of this valid portion YA will be described later.

At step Sd, at the time of attachment of each mask sheet 15 to the mask frame 11, both end portions of the mask sheet 15 are accurately welded at predetermined positions of the mask frame 11 to make the vapor deposition holes constituting the valid portions YA located at predetermined positions by using the alignment mark formed on the alignment sheet 14 as a reference while both the end portions of the mask sheet 15 are stretched (pulled) by application of force to each of both the end portions of the mask sheet 15 in an outward direction (in a direction away from each other) as indicated by arrow F4 in FIG. 7E.

In addition, at the time of stretching and welding of the mask sheet 15, the stretching and welding are performed while counter force is applied to the mask frame 11 according to an amount of deformation of the mask sheet 15 obtained after stretching and welding.

Here, an external shape of the valid portion YA formed on the mask sheet 15 is not an irregular shape but a square or rectangular shape. Hence, as compared with a mask sheet including a valid portion having an irregular shape, stress applied on the mask sheet can be prevented from being nonuniform when the mask sheet 15 is stretched. Accordingly, a positional offset of the vapor deposition holes in the vapor deposition mask can be prevented, and the mask sheet 15 can be attached to the mask frame 11 with high accuracy.

Then, after all the necessary sheets of the mask sheets 15 are attached to the mask frame 11 to cause all the openings defined by the covering sheets 12 and the hauling sheets 13 to be covered with the valid portions YA as illustrated in FIG. 8F, unnecessary portions located outside of the welded portions of the mask sheets 15 are cut off as illustrated at step Se in FIG. 7 and illustrated in FIG. 8F.

Next, in each of the valid portions YA having a square or rectangular shape of the mask sheet 15, a covering portion 25 configured to cover each of the vapor deposition holes is formed at the outside of the shape corresponding to the shape of the active region 3 (see FIG. 3), and thereby a first region YA having a shape corresponding to the shape of the active region 3 and a second region YA2 provided with the covering portion 25 are formed (covering-portion forming step).

Accordingly, the vapor deposition mask 10 is complete.

Next, as illustrated at step Sg in FIG. 7, the complete vapor deposition mask 10 is cleaned, and various mask inspections such as an inspection for foreign matters and an inspection for accuracy are performed. After this, vapor deposition masks 10 having no problem found in the mask inspections are stored in a stocker, and are supplied to a vapor deposition apparatus used at the vapor deposition step as needed.

Note that the order of step Se and step Sf may be reversed, and the covering portion 25 may be formed on each of the valid portions YA of the mask sheet 15 (step Sf) and then, the unnecessary portions of the mask sheet 15 may be cut (step Se).

Valid Portion YA

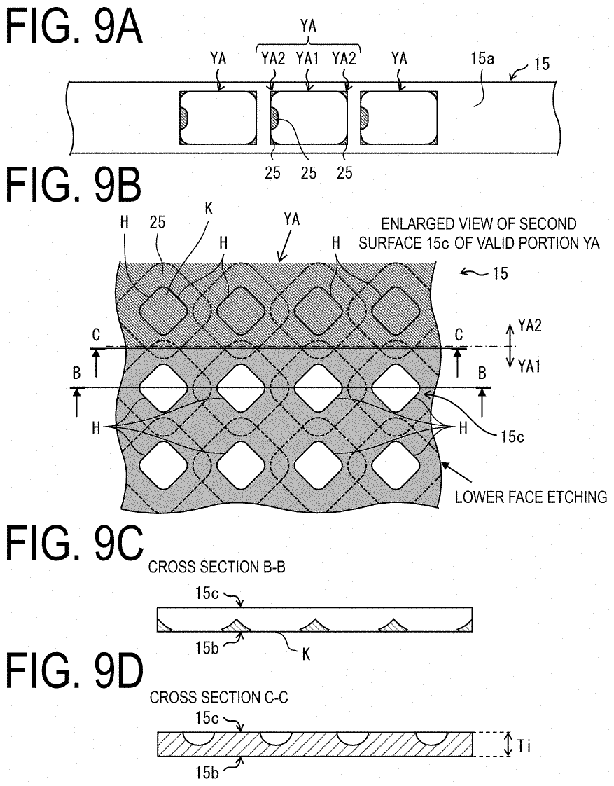

FIGS. 9A to 9D are views each illustrating a configuration of the mask sheet 15. FIG. 9A is a plan view illustrating the mask sheet 15. FIG. 9B is an enlarged view of the valid portion illustrated in FIG. 9A. FIG. 9C is a cross-sectional view taken along line B-B illustrated in FIG. 9B. FIG. 9D is a cross-sectional view taken along line C-C illustrated in FIG. 9B.

As illustrated in FIG. 9A, the mask sheet 15 includes a sheet portion 15a and the covering portion 25. The sheet portion 15a has a strip shape, and for example, an invar material or the like having a thickness ranging from 10 μm to 50 μm, preferably, a thickness of approximately 25 μm is used as a base material of the sheet portion 15a.

The material used to constituting the covering portion 25 is not limited to a resin, but is preferably a resin. This is because the covering portion 25 can be formed by application such as an ink-jet method as described later.

As the resin used to constitute the covering portion 25, a thermosetting resin or a photocurable resin such as an ultraviolet light photocurable resin can be used. In a case where a thermosetting resin is used to constitute the covering portion 25, an example of the thermosetting resin can include polyimide. In a case where a photocurable resin is used to constitute the covering portion 25, examples of the photocurable resin can include a high-durable acrylic resin, or an acrylic and/or epoxy resin and the like.

A photocurable resin is preferably used to constitute the covering portion 25, rather than a thermosetting resin. This is because, in a case where the covering portion 25 is cured by application of heat, heat is also applied to the mask sheet 15, and unnecessary force is applied on the mask sheet 15 owing to a difference in an expansion rate and a contraction rate between an invar material (metal) and a resin. In particular, in the case of a thermosetting resin, even when the mask sheet 15 is made of a material having a low thermal expansion coefficient such as an invar material, the material is cured in a state where the material is slightly expanded owing to an increase in a temperature for curing, and there is a possibility that accuracy may not be maintained.

Thus, a photocurable resin is used to constitute the covering portion 25, and thereby, application of heat becomes unnecessary at the time of curing the covering portion 25 applied in a liquid state, and an influence on accuracy, peeling-off of a covering resin, and occurrence of wrinkles on the mask sheet caused by a difference in a thermal expansion rate between a covering material (resin) and an invar material can be reduced. Accordingly, positional accuracy of a mask sheet can be maintained.

To prevent the light-emitting layer vapor-deposited from having a nonuniform thickness, the sheet portion 15a of the mask sheet 15 includes a sheet having a small thickness.

The plurality of valid portions YA arranged in a longitudinal direction of the mask sheets 15 are formed to be arranged between both the end portions of the mask sheets 15. In the valid portions YA, a plurality of vapor deposition holes H corresponding to the pixels are formed.

The external shape of each of the valid portions YA is a square or rectangular shape, rather than an irregular shape, to make stress as uniform as possible. In this embodiment, the external shape of each of the valid portions YA is a rectangular shape. Each of the valid portions YA is provided for each active region 3 of the TFT substrate 2, and the valid portions YA are formed to be spaced apart from each other.

The valid portions YA each include a first region YA1 having a shape corresponding to the shape of the active region 3 (see FIG. 3), and the second region YA2 located outside of the first region YA1, and provided with the covering portion 25 configured to cover a portion of the plurality of vapor deposition holes present in the valid portion YA.

The covering portion 25 is provided on the sheet portion 15a and at a portion not overlapping with the active region 3 of the TFT substrate 2 in each of the valid portions YA. The covering portion 25 defines an external shape of an irregular-shape portion of the first region YA1.

As illustrated in FIG. 9B, in each of the valid portions YA, the vapor deposition holes H present in the first region YA penetrate, and the vapor deposition holes H present in the second region YA2 are covered with the covering portion 25. The covering portion 25 does not need to be provided for each vapor deposition hole H present in the second region YA2, and may be formed to extend across each vapor deposition hole H present in the second region YA2. Accordingly, positional accuracy at the time of application by an ink-jet method of the covering material to be the covering portion 25 may slightly be low.

The vapor deposition holes H present in the first region YA are vapor deposition holes for patterning and forming the vapor-deposition layer for each pixel. The vapor deposition holes H present in the second region YA2 are dummy vapor deposition holes not contributing to patterning and forming of the vapor-deposition layer for each pixel.

At the vapor deposition step, the first region YA1 of the valid portion YA of the mask sheet 15 overlaps with the active region 3 of the TFT substrate 2 (see FIGS. 3 and 4), and the second region YA2 located outside of the first region YA1 and an edge portion surrounding the valid portion YA overlap with the frame region 44 (see FIGS. 3 and 4). Then, vapor deposition particles coming from the vapor deposition source pass through the vapor deposition holes H present in the first region YA1, and are vapor-deposited on the pixels of the active region 3 of the TFT substrate 2. At this time, the second region YA2 and the edge portion surrounding the valid portion YA of the mask sheet 15 overlap with the frame region 44 of the TFT substrate 2, and hence, vapor deposition particles are blocked by the second region YA2 and the edge portion surrounding the valid portion YA, and do not arrive at portions between the pixels and at the frame region 44.

In a case where the light-emitting layer is vapor-deposited on the TFT substrate through the mask sheet 15, the vapor deposition holes H are formed in the valid portion YA to correspond to a formation region for a light-emitting layer configured to emit light of any color of colors that the light-emitting layer emits. For example, in a case where the light-emitting layer configured to emit red light, the light-emitting layer configured to emit green light, and the light-emitting layer configured to emit blue light are formed in the active region 3, the vapor deposition holes H are formed in the same pattern as a pattern of any of the light-emitting layers configured to emit red light, the light-emitting layer configured to emit green light, and the light-emitting layer configured to emit blue light.

The vapor deposition holes H of the second region YA2 are the same as the vapor deposition holes H of the first region YA1 in a pitch and a shape.

The valid portion YA includes a combination of the first region YA1 and the second region YA2, and has a rectangular or square shape, rather than an irregular shape.

At step S101 illustrated in FIG. 7, the vapor deposition holes are prepared in the sheet portion 15a of the mask sheet 15, for example, in the following manner.

First, a negative-working or positive-working photosensitive resist is applied to both surfaces of the sheet portion 15a being an elongated plate made of an invar material to form a resist film on each of both main surfaces (a first surface and a second surface).

Then, the resist films of the first surface and the second surface are subjected to exposure and developing by using an exposure mask to form a resist pattern on each of both surfaces of the sheet portion 15a. Next, the resist pattern on the first surface is used as a mask to perform etching of a first surface 15b (surface facing the TFT substrate 2 at the time of vapor deposition) of the valid portion YA (etching of an upper face of the edge portion is not performed) to pattern and form openings K on the first surface 15b of the valid portion YA (at this stage, the openings K are still not the vapor deposition holes penetrating).

Then, the first surface 15b is covered with an etching resistant resin, and the resist pattern on a second surface 15c (surface opposite to the surface facing the TFT substrate 2 at the time of vapor deposition) as a mask to perform etching of the valid portion YA and a lower face of the edge portion. Accordingly, the vapor deposition holes H (through-holes) are formed in the valid portion YA by erosion from the second surface 15c side to form a plurality of recesses on the lower face of the edge portion.

The plurality of vapor deposition holes H of the valid portion YA are formed in a matrix shape or an oblique lattice pattern in the longitudinal direction and the short-hand direction (width direction) of the mask sheet 15. The openings K of the plurality of vapor deposition holes H (openings on the upper face) are shaped into a quadrangle shape including corners each having a round shape, or a circular shape or an elliptic shape to correspond to a shape of the opening of a pixel bank layer of the substrate. In the valid portion YA, etching of each of the vapor deposition holes H is performed from the second surface 15c side in a more extensive and deeper manner than from the first surface 15b side, and thereby, a shading portion (a height of a partition between two adjacent vapor deposition holes) is made small to increase vapor deposition accuracy and vapor deposition efficiency relative to a substrate.

The valid portion YA includes a configuration in which as a cross section is taken along line B-B passing through the center of two openings K adjacent in the lateral direction, the base material becomes minimum (cavity is maximum) as illustrated in FIG. 9C and as a cross section is taken along line C-C parallel to line B-B and passing through a point located equidistant from two openings K adjacent in the vertical direction, the base material becomes maximum (cavity is minimum) (a maximum thickness is equal to a thickness Ti of the base material) as illustrated in FIGS. 9C and 9D.

Accordingly, the mask sheet 15 to be stretched and welded to the mask frame 11 (FIG. 8E) is prepared.

As described above, after the mask sheet 15 is fixed to the mask frame 11, the covering portion 25 is formed on a portion of the valid portion YA as illustrated at step sf in FIG. 7 and illustrated in FIG. 8F.

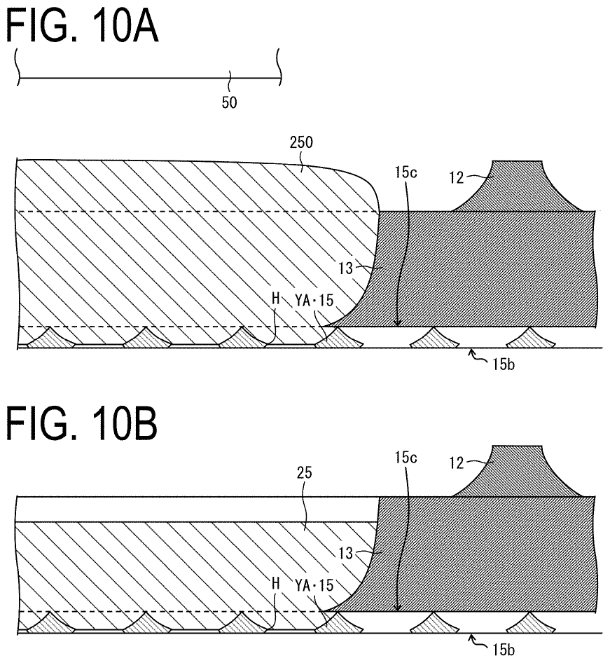

FIGS. 10A to 10B are views each illustrating a state where the covering portion 25 is formed on the valid portion YA of the mask sheet 15; FIG. 10A is a view illustrating a state where a covering material 250 is applied to the valid portion YA of the mask sheet 15, and FIG. 10B is a view illustrating a state where the covering material 250 is cured.

As an example, the case where the covering portion 25 is formed by using an ink-jet method will be described.

After the predetermined number of the mask sheets 15 are welded to the mask frame 11 as illustrated in FIGS. 8E and 8F, each of the mask sheets 15 is set to include the first surface 15b facing downward and the second surface 15c facing upward as illustrated in FIG. 10A.

Then, from a head of an ink-jet device 50, the covering material 250 is applied to a region located on the second surface 15c of each of the valid portions YA and being to be the second region YA2 (application step).

Then, when a predetermined amount of the covering material 250 is applied, the covering material 250 applied is cured (curing step). Accordingly, the covering portion 25 is formed on the second region YA2 of each of the valid portions YA as illustrated in FIG. 10B.

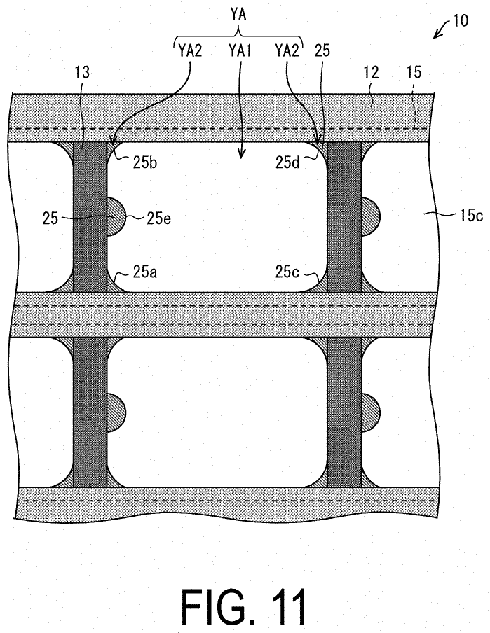

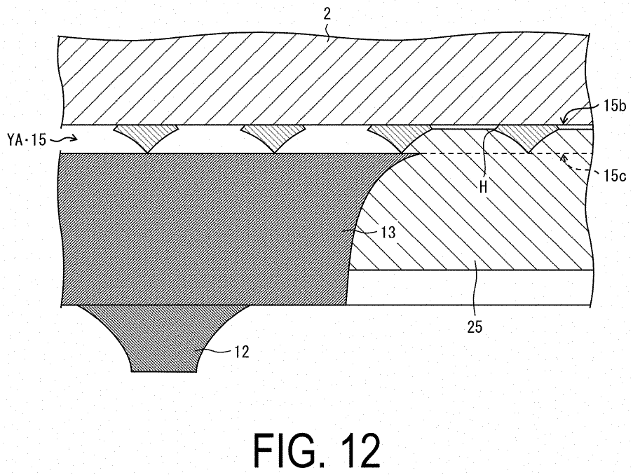

FIG. 11 is a view illustrating a state of a portion of the vapor deposition mask 10 as viewed from the second surface 15b side. FIG. 12 is a cross-sectional view of the vapor deposition mask 10 and the TFT substrate 2 at the time of performing vapor deposition at the vapor deposition step.

As illustrated in FIGS. 11 and 12, the covering portion 25 is provided on the second surface 15c of the mask sheet 15 located on the opposite side to the first surface 15b facing the TFT substrate 2. Hence, the first surface 15b of the mask sheet 15 can be prevented from having a raised shape due to the covering portion 25. Accordingly, the first surface 15b and the TFT substrate 2 can be brought into close contact with each other at the time of vapor deposition of the TFT substrate 2. As a result, a shadow due to the covering portion 25 can be prevented from occurring at the time of vapor deposition of the TFT substrate 2.

Note that the covering portion 25 may be layered not only on the valid portion YA but also on the covering sheet 12 between the valid portions YA and on the hauling sheet 13. In this embodiment, the covering sheet 12 and the hauling sheet 13 serve as a mask, and hence, the covering portion 25 is not formed on a region facing the covering sheet 12 and the hauling sheet 13 in the valid portion YA.

Main Effect

As illustrated in FIG. 11 and the like, the valid portion YA includes the first region YA having the shape corresponding to the shape of the active region 3 (see FIG. 3), and the second region YA2 located outside of the first region YA1 and provided with the covering portion 25 configured to cover the vapor deposition holes H. That is, the irregular-shape portion of the first region YA1 having the shape corresponding to the shape of the active region 3 is defined by providing the covering portion 25.

Hence, at the vapor deposition step, the first region YA1 can be used to pattern and form the vapor-deposition layer on each pixel present in the active region 3 having a desired external shape.

For example, the first region YA1 having the shape defined by the covering portion 25 has a shape in which curved portions 25a to 25d each having a rounded shape (round shape) corresponding to the four corners 43a to 43d of the active region 3 (see FIG. 3), and a notch 25e having an arc shape corresponding to a notch 43e.

The notch 25e is a notch in which the second region YA2 protrudes from one side of the first region YA1 toward an interior direction of the first region YA1. The curved portions 25a to 25d define a shape in which the four corners of the first region YA1 each have a round shape. The vapor deposition holes in the first region YA1 surrounded by the curved portion 25a, a protruding portion 25e, the curved portion 25b, the curved portion 25c, and the curved portion 25d are not covered with the covering portion 25, and are through-holes. On the other hand, the vapor deposition holes in the curved portion 25a, the protruding portion 25e, the curved portion 25b, the curved portion 25c, and the curved portion 25d and outside the first region YA1 are covered with the covering portion 25.

Accordingly, the first region YA1 having an irregular-shape portion can be used to form the vapor-deposition layer on each pixel of the active region having the same external shape as the external shape of the first region YA1, that is, having the irregular-shape portion.

Note that the shape of the first region YA1 is not limited to this, and may be any shape as long as the first region YA1 has the same shape as the shape of the active region 3 (FIG. 3).

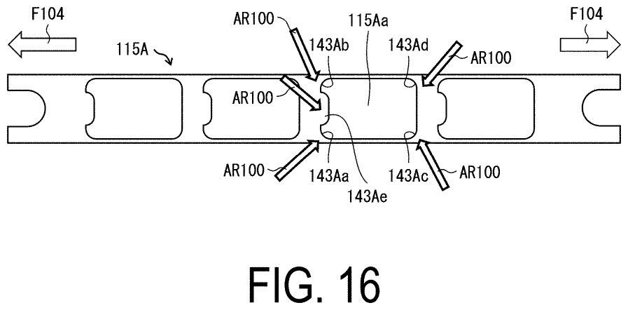

FIG. 16 is a plan view illustrating a configuration of a mask sheet according to a comparative example in which an external shape of a valid portion has an irregular shape.

As illustrated in FIG. 16, a method in which an external shape of a valid portion is an irregular shape corresponding to a shape of the active region to pattern and form a vapor-deposition layer by vapor deposition on an active region having an irregular shape is conceivable.

In a mask sheet 115, valid portions 115Aa each having an irregular shape different from a square or rectangular shape are formed to be arranged in a mask sheet 115A.

Vapor deposition holes being through-holes are patterned and formed in each of the valid portions 115Aa. The valid portions 115Aa each have four corners 143Aa to 143Ad each having a curved shape, rather than a right-angle shape. Further, in each of the valid portions 115Aa, a notched portion 143Ae recessed is formed on a portion of a straight side connecting the corner 143Aa and the corner 143Ab.

At the time of attachment to the mask frame of the mask sheet 115A including such a valid portion 115Aa having an irregular shape and formed, outward force is applied as indicated by arrow F104 in FIG. 16 to both end portions of the mask sheet 115A, and then, stress applied on regions in the periphery of the four corners 143Aa to 143Ad indicated by arrow AR100 and on regions in the periphery of the irregular-shape portion such as regions in the periphery of the notched portion 143Ae indicated by arrow AR101 becomes nonuniform, and thereby, an amount of deformation becomes nonuniform. As a result, positional accuracy of each vapor deposition hole in the vapor deposition mask to which the mask sheet 115A is attached deteriorates.

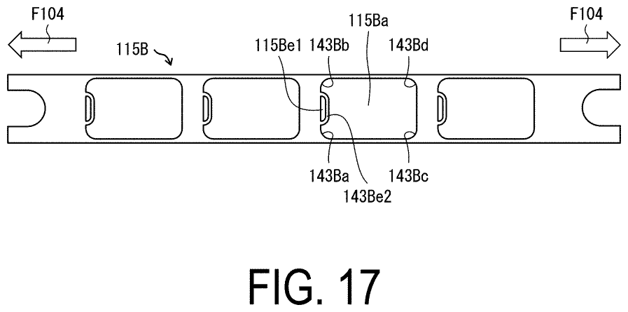

FIG. 17 is a plan view illustrating a configuration of a modification example of a mask sheet in which an external shape of a valid portion has an irregular shape.

In a valid portion 115Ba of a mask sheet 115B illustrated in FIG. 17, four corners 143Ba to 143Bd are curved. However, a method in which a full etching portion 143Be1 and a half etching portion 143Be2 are formed in a region corresponding to the notched portion 143Ae (see FIG. 16) is conceivable. Vapor deposition holes present in the full etching portion 143Be1 are through-holes, and recessed portions not penetrating are formed in a vapor-deposition-hole forming region present in the half etching portion 143Be2.

Accordingly, at the time of attachment of the mask sheet 115B to the mask frame, outward force is applied to both end portions of the mask sheet 115B as indicated by arrow F104 in FIG. 17, and then, nonuniformity of stress applied on regions in the periphery of the full etching portion 143Be1 and the half etching portion 143Be2 can be reduced to be lower than nonuniformity of stress applied on a region in the periphery of the notched portion 143Ae illustrated in FIG. 16. However, the stress applied on the regions in the periphery of the full etching portion 143Be1 and the half etching portion 143Be2 is still nonuniform, and the nonuniformity of the stress applied on the regions in the periphery of the four corners 143Ba to 143Bd still remains.

On the other hand, in the vapor deposition mask 10 according to this embodiment, the valid portion YA of the mask sheet 15 has a rectangular or square shape as described above. Then, the covering portion 25 is provided on the valid portion YA to form the first region YA1 having the external shape corresponding to the external shape of the irregular-shape portion of the active region 3.

Accordingly, the external shape of the valid portion YA particularly required of positional accuracy in the vapor deposition mask 10 does not need to correspond to the external shape of the active region 3 on which the light-emitting layer needs to be vapor-deposited. Hence, even when the external shape of the active region on which the vapor-deposition layer needs to be vapor-deposited has an irregular shape, the external shape of the valid portion YA of the mask sheet 15 can be a rectangular or square shape (rectangular shape in this embodiment), rather than an irregular shape.

Hence, unlike the case where the valid portion has an irregular shape, nonuniform stress can be prevented from being applied on the mask sheet 15 even when the mask sheet 15 is stretched at the time of attachment of the mask sheet 15 to the mask frame 11. Accordingly, the vapor deposition mask 10 having high positional accuracy for vapor deposition holes H in the vapor deposition mask 10. That is, according to the vapor deposition mask 10, the light-emitting layer can be vapor-deposited for each pixel on the TFT substrate 2 with high accuracy.

Note that, in addition, the external shape of the active region 3 on which the light-emitting layer is formed in the TFT substrate 2 can be an irregular shape different from a square or rectangular shape, and an organic EL display panel having a high design property can be obtained.

In addition, in this embodiment, the mask sheet 15 is stretched and is welded to the mask frame 11 (at step Sd in FIG. 7 and in FIG. 8E), and then, the covering portion 25 is formed in the valid portion YA (at step Sf in FIG. 7 and in FIG. 8F). Namely, in this embodiment, the application step and the curing step are performed after the mask-sheet attachment step. Accordingly, deterioration in mask accuracy due to nonuniform stress caused by stretching of the mask sheet 15 after the covering portion 25 is formed can be prevented, and breaking of the covering portion 25 due to stretching of the mask sheet 15 can be prevented.

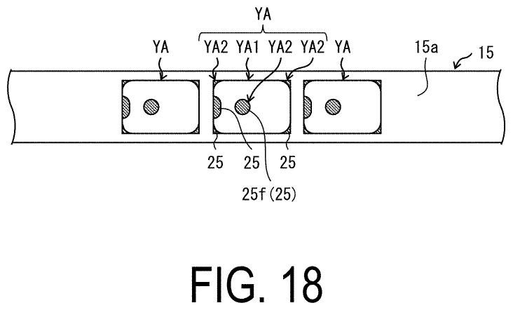

In addition, the covering portion 25 can be formed by application using an ink-jet method or the like, and hence, can be used not only to define the external shape of the irregular shape but also can be used to define a floating-island shape by providing a floating island portion 25f by using the covering portion 25 as illustrated in FIG. 18. The floating island portion 25f is a region surrounded by the first region YA1 and is a region different from the first region YA1. In other words, the floating island portion 25f is an isolated region located in the first region YA1 without being in contact with the external shape of the first region YA1, and including a plurality of vapor deposition holes covered. A floating island portion having the same shape as a shape of the floating island portion 25f can be provided by using this floating island portion 25f at the same position as a position of the floating island portion 25f in the active region 3. The floating island portion provided in the active region 3 refers to a region surrounded by the active region 3 and is a region different from the active region 3. In other words, the floating island portion in the active region 3 is an isolated region located within the active region 3 without being not in contact with the external shape of the active region 3, and including no vapor-deposition layer formed.

Thus, even when the floating island is provided in the active region 3, a floating island in the active region 3 can be formed by providing the floating island portion 25f in the valid portion YA.

Thus, according to the vapor deposition mask 10, a positional offset on the vapor deposition mask 10 of the vapor deposition holes H formed in the valid portion YA can be suppressed even when the external shape of the active region 3 is an irregular shape different from a rectangular or square shape.

Additionally, the external shape of the valid portion YA does not need to be changed even when the external shape of the active region 3 is changed. Hence, commonality of the mask sheet 15 including the valid portion YA formed can be achieved between substrates having various external shapes.

### Second Embodiment

A covering portion 25 may be applied to a valid portion YA prior to stretching and welding of a mask sheet 15, and after the mask sheet 15 is stretched and welded, the covering portion 25 may be cured completely.

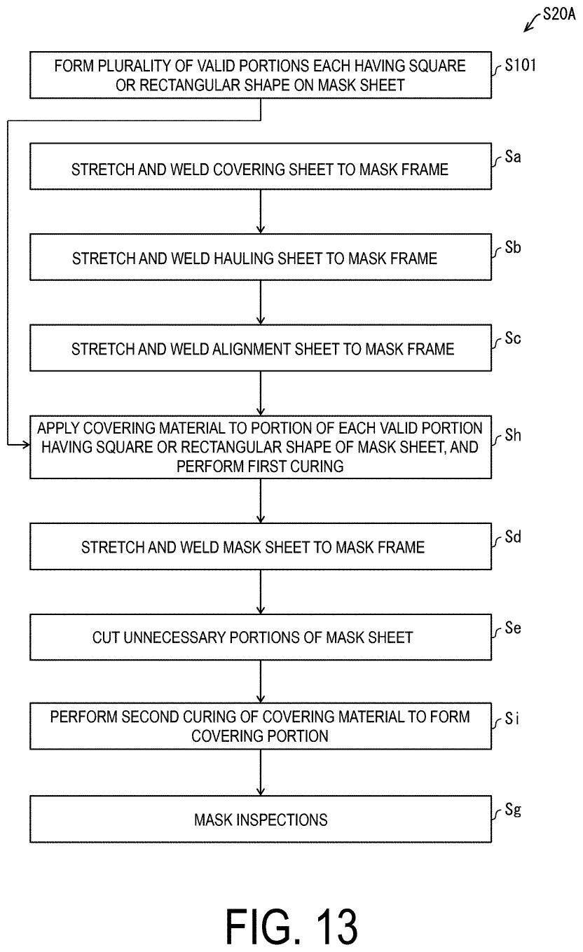

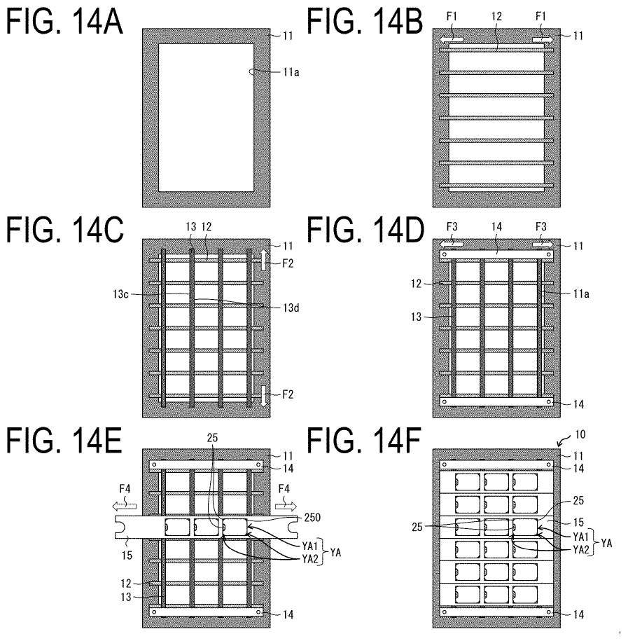

FIG. 13 is a view illustrating a vapor deposition step for a light-emitting layer of an organic EL display panel according to a second embodiment. FIGS. 14A to 14F are views each illustrating a state where a vapor deposition mask according to the second embodiment is prepared. FIG. 14A is a plan view illustrating a mask frame. FIG. 14B is a view illustrating a state where a covering sheet is attached to the mask frame. FIG. 14C is a view illustrating a state where a hauling sheet is attached to the mask frame. FIG. 14D is a view illustrating a state where an alignment sheet is attached to the mask frame. FIG. 14E is a view illustrating a state where a mask sheet is attached to the mask frame. FIG. 14F is a plan view illustrating the vapor deposition mask prepared.

In this embodiment, step S20A illustrated in FIG. 13 is performed instead of step S20 illustrated in FIG. 7.

Steps Sa to Sc illustrated in FIG. 13 and FIGS. 14A to 14D are the same as steps Sa to Sc illustrated in FIG. 7 and FIGS. 8A to 8D.

As illustrated at step Sc in FIG. 13 and illustrated in FIG. 14D, an alignment sheet 14 is attached to a mask frame 11 to make an alignment mark located at a predetermined position.

Next, as illustrated at step Sh in FIG. 13 and illustrated in FIG. 14E, a covering material 250 (FIG. 10A) for covering vapor deposition holes is applied outside of a shape corresponding to a shape of an active region 3 (see FIG. 3) in each valid portion YA of the mask sheet 15 where a plurality of the valid portions YA are formed in advance at a valid-portion forming step (application step). Then, the covering material 250 applied is preliminarily cured (first curing, preliminary curing) to the extent that the covering material 250 is not completely cured (first curing step).

At the first curing step, in a case where a thermosetting resin is used for the covering material 250, the covering material 250 is heated at a low temperature or for a short heating time to the extent that the covering portion 25 completely cured is not formed. In addition, in a case where a photocurable resin is used for the covering material 250, the covering material 250 is irradiated with light such as ultraviolet light at a low light level or for a short irradiation time to the extent that the covering portion 25 completely cured is not formed. In addition, at the first curing step, in a case where any of a thermosetting resin and a photocurable resin is used for the covering material 250, the covering material 250 may be cured preliminarily at a reduced pressure.

Then, as illustrated at step Sd in FIG. 13 and illustrated in FIG. 14E, a plurality of the mask sheets 15 are attached to the mask frame 11 (mask-sheet attachment step).

At step Sd, at the time of attachment of each mask sheet 15 to the mask frame 11, both end portions of the mask sheet 15 are welded with high accuracy at predetermined positions of the mask frame 11 to make the vapor deposition holes constituting the valid portion YA located at predetermined positions by using the alignment mark formed on the alignment sheet 14 as a reference while both the end portions of the mask sheet 15 are stretched (pulled) by application of force to each of both the end portions of the mask sheet 15 in an outward direction (in a direction away from each other) as indicated by arrow F4 in FIG. 14E.

Here, the covering material 250 preliminarily cured is provided in the valid portion YA of the mask sheet 15. However, since the covering material 250 is not completely cured, the covering material 250 follows the extension of the mask sheet 15 and extends even when the mask sheet 15 is stretched and extends. Hence, a fault due to the stretching of the mask sheet 15 can be prevented from occurring in the covering portion 25.

Then, after all the necessary sheets of the mask sheets 15 are attached to the mask frame 11 to cause all openings defined by covering sheets 12 and hauling sheets 13 to be covered with the valid portions YA as illustrated in FIG. 14F, unnecessary portions located outside of the welded portions of each of the mask sheets 15 are cut off as illustrated at step Se in FIG. 13 and illustrated in FIG. 14F.

Then, as illustrated at step Si in FIG. 13 and illustrated in FIG. 14F, the covering material 250 preliminarily cured is caused to be completely cured (second curing) (second curing step). Accordingly, the covering portion 25 is formed in each of the valid portions YA (covering-portion forming step).

At the second curing step, in a case where a thermosetting resin is used for the covering material 250, the covering material 250 is heated at a high temperature or for a sufficient heating time to the extent that the covering material 250 is completely cured. In addition, in a case where a photocurable resin is used for the covering material 250, the covering material 250 is irradiated with light such as ultraviolet light at a high light level or for a sufficient irradiation time to the extent that the covering material 250 is completely cured.

Accordingly, a vapor deposition mask 10 is complete.

Next, as illustrated at step Sg in FIG. 13, the vapor deposition mask 10 complete is cleaned, and various mask inspections such as an inspection for foreign matters and an inspection for accuracy are performed. Subsequently, vapor deposition masks 10 having no problem found in the mask inspections are stored in a stocker, and are supplied to a vapor deposition apparatus used at the vapor deposition step as needed.

Note that the order of step Se and step Si is reversed, and the covering portion may first be formed on each of the valid portions YA of the mask sheet 15 (step Si) and then, unnecessary portions of the mask sheet 15 may be cut (step Se).

Thus, in the second embodiment, the curing step includes the first curing step for preliminarily curing the covering material 250, and the second curing step for further curing the covering material 250 preliminarily cured to form the covering portion 25. Then, the application step and the first curing step are performed before the mask-sheet attachment step, and the second curing step is performed after the mask-sheet attachment step. Accordingly, the covering portion 25 can be provided with sufficiently high positional accuracy to define a shape of a first region YA1 in the valid portion YA.

Note that, at the application step, the covering material 250 may be applied to the second region YA2 in a state where both end portions of the alignment sheet 14 are stretched by application of force to each of both the end portions of the alignment sheet 14 in an outward direction (in a direction away from each other). Accordingly, a fault due to the stretching of the mask sheet 15 can be prevented more reliably from occurring in the covering portion 25.

In addition, in this embodiment, the mask sheet 15 is attached to the mask frame 11 after the covering material 250 to be the covering portion 25 is applied, and hence, the covering portion 25 is not layered on the hauling sheet 13 between the valid portions YA.

In addition, the display according to the first and second embodiments is not particularly limited, as long as the display is a display panel including a display element. The display element is a display element of which luminance and transmittance are controlled by an electric current, and examples of the electric current-controlled display element include an organic Electro Luminescence (EL) display provided with an Organic Light Emitting Diode (OLED), an EL display such as an inorganic EL display provided with an inorganic light emitting diode, and a QLED display provided with a Quantum Dot Light Emitting Diode (QLED).

### Supplement

A vapor deposition mask according to a first aspect provides a vapor deposition mask configured to be used to vapor-deposit a vapor-deposition layer on each of pixels of a vapor deposited substrate provided with a plurality of active regions on which the pixels contributing to displaying are arranged, the vapor deposition mask including: a mask sheet provided with a valid portion provided for each of the plurality of active regions and including a plurality of vapor deposition holes, where the valid portion includes a first region and a second region, the first region has a shape corresponding to a shape of each of the plurality of active regions, and the second region is a region different from the first region, and is provided with a covering portion configured to cover a portion of the plurality of vapor deposition holes.

In the vapor deposition mask according to a second aspect, the covering portion may be provided to extend across the plurality of vapor deposition holes present in the second region.

In the vapor deposition mask according to a third aspect, the covering portion may be provided on a second surface of the mask sheet located on an opposite side to a first surface facing the vapor deposited substrate.

In the vapor deposition mask according to a fourth aspect, the covering portion may be made of a resin.

In the vapor deposition mask according to a fifth aspect, the covering portion may be made of a photocurable resin.

In the vapor deposition mask according to a sixth aspect, the valid portion may have a square or rectangular shape.

In the vapor deposition mask according to a seventh aspect, the second region may include a notch on one side of the first region, the notch may protrude from the one side toward an interior direction of the first region, and the plurality of vapor deposition holes in a region located outside of the first region and surrounded by the notch may be covered with the covering portion.

In the vapor deposition mask according to an eighth aspect, the second region may include a floating island portion being a region surrounded by the first region, and being not in contact with an external shape of the first region.

In a manufacturing method for a vapor deposition mask according to a ninth aspect provides a manufacturing method for a vapor deposition mask used to vapor-deposit a vapor-deposition layer on each of pixels of a vapor deposited substrate provided with a plurality of active regions on which the pixels contributing to displaying are arranged, the method including: a vapor-deposition-hole forming step for forming a plurality of vapor deposition holes in a mask sheet to provide a valid portion for each of the plurality of active regions; and a covering-portion forming step for forming, outside of a shape of the valid portion corresponding to a shape of each of the plurality of active regions in the valid portion, a covering portion configured to cover a portion of the plurality of vapor deposition holes, to provide a first region having a shape corresponding to a shape of each of the plurality of active regions and to provide a second region provided with the covering portion.

In the manufacturing method for a vapor deposition mask according to a tenth aspect, the covering-portion forming step may include an application step for applying a covering material to a region located on the mask sheet and being to be the second region, and a curing step for curing the covering material applied at the application step to form the covering portion.

In the manufacturing method for a vapor deposition mask according to an eleventh aspect, the method may include a mask-sheet attachment step for attaching the mask sheet to a mask frame having a frame shape while the mask sheet is stretched, and the application step and the curing step may be performed after the mask-sheet attachment step.

In the manufacturing method for a vapor deposition mask according to a twelfth aspect, the method may include a mask-sheet attachment step for attaching the mask sheet to a mask frame having a frame shape while the mask sheet is stretched, the curing step may include a first curing step for preliminarily curing the covering material and a second curing step for further curing the covering material preliminarily cured to form the covering portion, the application step and the first curing step may be performed before the mask-sheet attachment step, and the second curing step may be performed after the mask-sheet attachment step.

In the manufacturing method for a vapor deposition mask according to a thirteenth aspect, the valid portion may have a square or rectangular shape.

The disclosure is not limited to each of the embodiments described above, and various modifications can be implemented within the scope of the claims. Embodiments obtained by appropriately combining the technical approaches disclosed in each of the different embodiments also fall within the technical scope of the disclosure. Further, novel technical features can be formed by combining the technical approaches disclosed in each of the embodiments.

### REFERENCE SIGNS LIST

1 Substrate
2 TFT substrate (vapor deposited substrate)
3 Active region
4 Frame-shaped bank
5 Sealing layer
6, 8 Inorganic film
7 Organic film
9 Organic EL display panel formation region
10 Vapor deposition mask
11 Mask frame
12 Covering sheet
13 Hauling sheet
14 Alignment sheet
15 Mask sheet
15a Sheet portion
25 Covering portion
25a Curved portion
30 Electronic device
40 Touch panel
41 Touch sensor
42 Organic EL display panel
43 Display region
44 Frame region
50 Ink-jet device
70 Vapor deposition source
80 Light-emitting layer
H Vapor deposition hole
pix Pixel
YA2 Second region of valid portion YA
YA1 First region of valid portion YA

1. A vapor deposition mask configured to be used to vapor-deposit a vapor-deposition layer on each of pixels of a vapor deposited substrate provided with a plurality of active regions on which the pixels contributing to displaying are arranged, the vapor deposition mask comprising:
a mask sheet provided with a valid portion provided for each of the plurality of active regions and including a plurality of vapor deposition holes arranged,
wherein the valid portion includes a first region and a second region,
the first region has a shape corresponding to a shape of each of the plurality of active regions,
the second region is a region different from the first region, and is provided with a covering portion configured to cover a portion of the plurality of vapor deposition holes, and
the covering portion is made of a photocurable resin.

2. The vapor deposition mask according to claim 1,
wherein the covering portion is provided to extend across the plurality of vapor deposition holes present in the second region.

3. The vapor deposition mask according to claim 1,
wherein the covering portion is provided on a second surface of the mask sheet located on an opposite side to a first surface facing the vapor deposited substrate.

4-5. (canceled)

6. The vapor deposition mask according to claim 1,
wherein the valid portion has a square or rectangular shape.

7. The vapor deposition mask according to claim 1,
wherein the first region includes a notch in which the second region protrudes from one side of the first region toward an interior direction, and
the plurality of vapor deposition holes in a region located outside of the first region and surrounded by the notch are covered with the covering portion.

8. The vapor deposition mask according to claim 1,
wherein the second region includes a floating island portion being a region surrounded by the first region, and being not in contact with an external shape of the first region.

9. A manufacturing method for a vapor deposition mask used to vapor-deposit a vapor-deposition layer on each of pixels of a vapor deposited substrate provided with a plurality of active regions on which the pixels contributing to displaying are arranged, the method comprising:
a vapor-deposition-hole forming step for forming a plurality of vapor deposition holes in a mask sheet to provide a valid portion for each of the plurality of active regions; and
a covering-portion forming step for forming, outside of a shape of the valid portion corresponding to a shape of each of the plurality of active regions in the valid portion, a covering portion configured to cover a portion of the plurality of vapor deposition holes, to provide a first region having a shape corresponding to a shape of each of the plurality of active regions and to provide a second region provided with the covering portion,
wherein the covering-portion forming step includes
an application step for applying a covering material to a region located on the mask sheet and being to be the second region, and
a curing step for curing the covering material applied at the application step to form the covering portion.

10. (canceled)

11. The manufacturing method for a vapor deposition mask according to claim 9, comprising:
a mask-sheet attachment step for attaching the mask sheet to a mask frame having a frame shape while the mask sheet is stretched,
wherein the application step and the curing step are performed after the mask-sheet attachment step.

12. The manufacturing method for a vapor deposition mask according to claim 9, comprising:
a mask-sheet attachment step for attaching the mask sheet to a mask frame having a frame shape while the mask sheet is stretched,
wherein the curing step includes a first curing step for preliminarily curing the covering material and a second curing step for further curing the covering material preliminarily cured to form the covering portion,
the application step and the first curing step are performed before the mask-sheet attachment step,
after the first curing step, at the mask-sheet attachment step, the mask sheet is attached to the mask frame while the mask sheet is stretched, and
the second curing step is performed after the mask-sheet attachment step.

13. The manufacturing method for a vapor deposition mask according to claim 9,
wherein the valid portion has a square or rectangular shape.
